(19) United States
(12) Patent Application Publication
(10) Pub. No.: US 2019/0244002 A1
(43) Pub. Date: Aug. 8, 2019

(54) DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Jian YE, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 15/756,071

(22) PCT Filed: Feb. 26, 2018
(86) PCT No.: PCT/CN2018/077174

§ 371 Date: Feb. 28, 2018

(30) Foreign Application Priority Data
Feb. 6, 2018 (CN) 201810115608.7

(51) Int. Cl. G06K 9/00; H01L 27/32; H01L 51/52

(52) U.S. Cl. CPC G06K 9/00013; H01L 27/323; H01L 27/3234; G06K 9/0004; H01L 51/52; H01L 51/529; G06K 9/0002; H01L 27/3244

(57) ABSTRACT

The present invention provides a display device. The device is provided with an opening on a film structure on a back surface of a display panel, and a fingerprint recognition module is arranged in the opening, thereby reducing distance between the fingerprint recognition module and the back surface of the display panel, to improve fingerprint recognition accuracy. In addition, the fingerprint recognition module can also be located at any position in middle range of the display panel, and is not limited to the edge region at the bottom of the display panel, so as to improve a screen ratio of the display device.

### FIELD OF INVENTION

This disclosure relates to a field of liquid crystal displays, and more particularly to a display device.

### BACKGROUND OF INVENTION

Present, display devices such as mobile phones and tablets are mainly locked/unlocked by fingerprints. Modern fingerprint recognition mainly adopts capacitive sensing technology. Principle of fingerprint recognition is that, when a finger touches top of a fingerprint recognition module, it will turn on capacitive electrodes arrayed in the fingerprint recognition module. At the same time, protruding ridges of the finger make direct contact with the capacitive electrodes, and depressed valleys of the finger are far away from the capacitive electrodes, so that different sensing capacitance can be produced. Fingerprint information of a contact person will be obtained by converting the sensing capacitance into an image data, and hence the subsequent fingerprint comparison and identification operation can be executed.

Prior art display devices increase thickness of a front glass cover to protect internal elements, which increases not only distance between the fingerprint recognition module and a human finger, but also greatly reduces performance of the fingerprint recognition module to identify and sense the human finger. In current solutions, an independent fingerprint recognition module usually needs to open a hole in the front glass cover, and then embed the fingerprint recognition module into the hole. But this affects integrity of the front glass cover of the display device, and also increase manufacturing process difficulty of the front glass cover, and thereby increasing manufacturing cost. In addition, the independent fingerprint recognition module is located on the upper and/or lower edges of the display device, which usually occupies a lot of space of the display area of the display device, thereby reducing screen ratio of the display area.

### SUMMARY OF INVENTION

The object of the present invention to provide a display device capable of improving a screen ratio of the display device, to improve fingerprint recognition accuracy, thereby solving the technical problems of display device in the prior art.

The embodiment of the present invention provides a display device. The device comprising:

a display panel having a display surface and a back surface disposed opposite to each other, wherein the display surface has a display area for displaying images;

a thin film structure disposed on the back surface of the display panel, wherein the thin film structure is provided with an opening; and

a fingerprint recognition module configured to identify fingerprint information input from the display area, wherein the fingerprint recognition module is disposed in the opening of the film structure;

wherein the thin film structure comprises a support film, a buffer film, a heat sink and a shielding film stacked on the back surface of the display panel; and

wherein the fingerprint recognition module is an optical fingerprint recognition device or an ultrasonic fingerprint recognition device.

In the display device according to one embodiment of the present invention, the opening penetrates through at least one of the support film, the buffer film, the heat sink, and the shielding film from an outside to an inside of the thin film structure.

In the display device according to one embodiment of the present invention, the display panel is an active matrix organic light-emitting diode panel.

In the display device according to one embodiment of the present invention, size of the opening is same as size of the fingerprint recognition module.

The embodiment of the present invention provides a display device, a thickness of the fingerprint recognition module is equal to a thickness of the thin film structure.

In the display device according to one embodiment of the present invention, the display area is provided with a fingerprint recognition area, and wherein the opening corresponds to and is located under the fingerprint recognition area.

The embodiment of the present invention further provides a display device. The device comprising:

a display panel having a display surface and a back surface disposed opposite to each other, wherein the display surface has a display area for displaying images;

a thin film structure disposed on the back surface of the display panel, wherein the thin film structure is provided with an opening; and

a fingerprint recognition module configured to identify fingerprint information input from the display area, wherein the fingerprint recognition module is disposed in the opening of the film structure;

In the display device according to one embodiment of the present invention, the thin film structure comprises a support film, a buffer film, a heat sink and a shielding film stacked on the back surface of the display panel.

In the display device according to one embodiment of the present invention, the opening penetrates through at least one of the support film, the buffer film, the heat sink, and the shielding film from an outside to an inside of the thin film structure.

In the display device according to one embodiment of the present invention, the display panel is an active matrix organic light-emitting diode panel.

In the display device according to one embodiment of the present invention, the fingerprint recognition module is an optical fingerprint recognition device or an ultrasonic fingerprint recognition device.

In the display device according to one embodiment of the present invention, size of the opening is same as size of the fingerprint recognition module.

In the display device according to one embodiment of the present invention, a thickness of the fingerprint recognition module is equal to a thickness of the thin film structure.

In the display device according to one embodiment of the present invention, the display area is provided with a fingerprint recognition area, and wherein the opening corresponds to and is located under the fingerprint recognition area.

The embodiment of the present invention provides a display device. The device is provided with an opening in a film structure on a back surface of a display panel, and a fingerprint recognition module is arranged in the opening, thereby reducing the distance between the fingerprint recognition module and the back surface of the display panel, to improve the fingerprint recognition accuracy. In addition, the fingerprint recognition module can also be located at any position in middle range of the display panel, and is not limited to the edge region at the bottom of the display panel, so as to improve a screen ratio of the display device.

### DESCRIPTION OF DRAWINGS

In order to more clearly describe the embodiments of this disclosure or the conventional technical solutions, the description is used to make a simple introduction of the drawings used in the following embodiments. The following description of the drawings are merely some embodiments of this disclosure. In order, more clearly describe the embodiments of this disclosure or the conventional technical solutions, the description is used to make a simple introduction of the drawings used in the following embodiments. The following description of the drawings are merely some embodiments of this disclosure. Those of ordinary skill in the art can also obtain other drawings based on these drawings without creative effort.

FIG. 1 is a schematic view of a structure of a display device according to a preferred embodiment of this present invention;

FIG. 2 is a cross-sectional view taken along line A-B of the display device of FIG. 1, according to an exemplary embodiment of this present invention; and

FIG. 3 is another cross-sectional view taken along line A-B of the display device of FIG. 1, according to an exemplary embodiment of this present invention.

### DETAILED DESCRIPTION OF PREFERRED EMBODIMENTS

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

Throughout this specification and in the drawings like parts will be referred to by the same reference numerals.

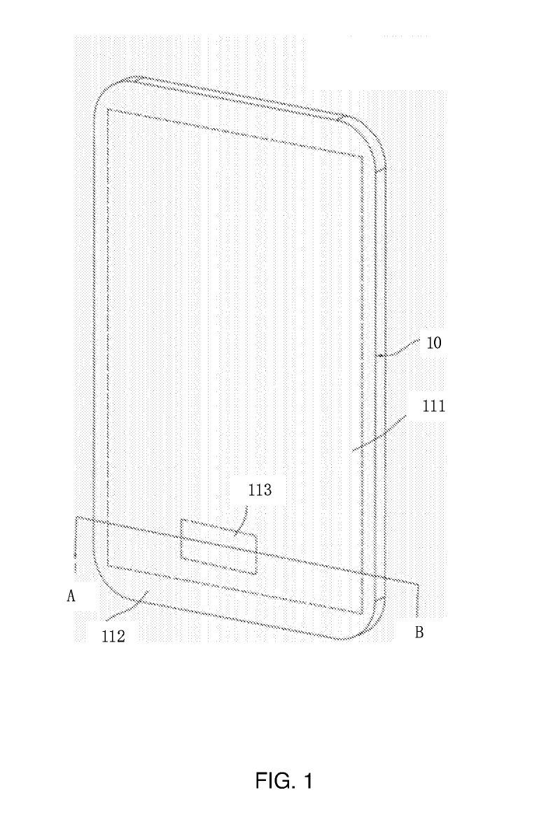

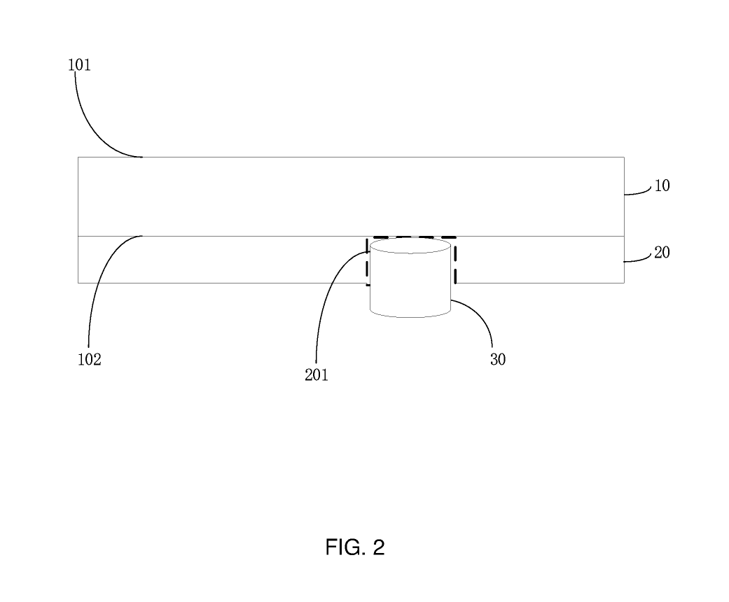

Please refer to FIGS. 1 to 2. FIG. 1 is a schematic view of a structure of a display device according to a preferred embodiment of this present invention. FIG. 2 is a cross-sectional view taken along line A-B of the display device of FIG. 1, according to an exemplary embodiment of this present invention is shown. As shown in FIGS. 1 to 2, at least one preferred embodiment of the present invention provides a display device with fingerprint recognition in which, a display panel 10, a thin film structure 20, and a fingerprint recognition module 30 are included in a display device. The display panel 10 has a display surface 101 and a back surface 102 disposed opposite to each other, and the display surface 101 has a display area 111 for displaying images. In a case of fingerprint recognition, the surface of the display area 111 may be set as a finger contact surface or a fingerprint recognition area may be provided on the surface of the display area 111 for finger pressing. The thin film structure 20 disposed on the back surface 102 of the display panel 10, and the thin film structure 20 is provided with an opening 201. Wherein the fingerprint recognition module 30 is disposed in the opening 201 of the thin film structure 20 on the back surface 102 of the display panel 10, and the fingerprint recognition module 30 configured to identify a fingerprint information input from the display area 111. Because the fingerprint recognition module 30 is located in the opening 201, the distance between the fingerprint recognition module 30 and the display area 111 for receiving the user fingerprint information can be shortened, thereby improving accuracy and sensitivity of the fingerprint recognition module 30. In addition, for clarity, the display panel 10 in the embodiment of the present invention is preferably an active matrix organic light-emitting diode display panel, which are not limited herein, and will be described below.

It is noted that description, according to the above structure, when the fingerprint recognition module 30 is mounted directly below the thin film structure 20 since the fingerprint recognition module 30 itself has a certain thickness, which not only increases the overall thickness of the display device but also affects sensing accuracy of the fingerprint recognition module 30. Therefore, in the display device provided by the embodiment of the present disclosure, since the device is provided with the opening 201 in the thin film structure 20 on the back surface 102 of the display panel 10, and the fingerprint recognition module 30 is disposed in the opening 201, which can reduce the distance between the fingerprint recognition module 30 and the back surface 102 of the display panel 10 while not affecting the overall thickness of the display device, so as to meet the design requirement for thinness. In view of the above, when the finger touches the display area 111 above the fingerprint recognition module 30, because the fingerprint recognition module 30 is located within the opening, that not only shorten distance between the fingerprint recognition module 30 and the display region 111 for receiving user fingerprint information, but also reduce distance between the fingerprint recognition module 30 and the finger, so as to improve accuracy and sensitivity of the fingerprint recognition module 30.

More specifically, according to the above structure, wherein a size of the opening 201 of the thin film structure 20 is the same as a size of the fingerprint recognition module 30. In which, by providing an opening 201 in the thin film structure 20, and the fingerprint recognition module 30 is disposed in the opening 201. In order to minimize the influence with the opening 201 is configured in the display device, the size of the opening 201 can be made to be same as the size of the fingerprint recognition module 30, so that the fingerprint recognition module 30 and the opening 201 can be completely matched.

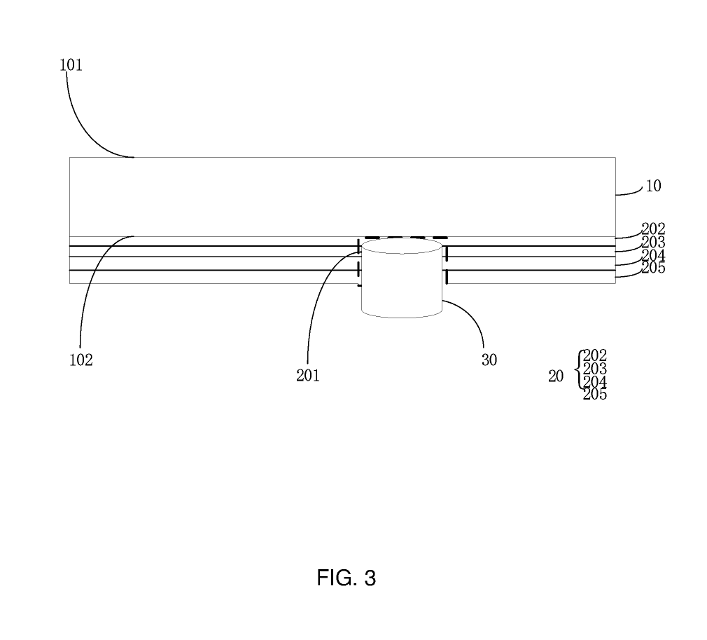

Referring to FIG. 3, another cross-sectional view taken along line A-B of the display device of FIG. 1, according to an exemplary embodiment of this present invention is shown. As shown in FIG. 3, according to the above structure, wherein the thin film structure 20 disposed on the back surface 102 of the display panel 10, the thin film structure 20 includes a support film 202, a buffer film 203, a heat sink 204 and a shielding film 205 respectively stacked on the back surface 102 of the display panel 10. The support film 202, the buffer film 203, the heat sink 204 and the shielding film 205 can each perform some corresponding auxiliary functions on the display panel 10, so that the display panel 10 is more stable. In particular, the support film 202 can be used to support the display panel 10. The buffer film 203 may be used to provide cushioning for the display panel 10. The heat sink 204 can be used to provide heat dissipation to the display panel 10. The shielding film 205 can be used to shield the display Panel 10 to obstruct the external environment. Specifically, in the embodiments which are not illustrated, the thin film structure 20 is not limited to the above configuration of the film layer depending on the design requirements. It will add other layers or delete some layers can be made to the thin film structure 20 of the present invention without departing from the scope or spirit of the invention.

More specifically, according to the above structure, wherein the opening 201 penetrates through at least one of the support film 202, the buffer film 203, the heat sink 204, and the shielding film 205 from an outside to an inside of the thin film structure 20. The thin film structure 20 includes the support film 202, the buffer film 203, the heat sink 204 and the shielding film 205 respectively stacked on the back surface 102 of the display panel 10. That is, in the film structure 20, the shielding film 205, the heat sink 204, the buffer film 203 and the support film 202 are sequentially arranged from outside to inside of the thin film structure 20. In addition, the opening 201 may penetrate only the shielding film 205. The opening 201 may also continuously penetrate the shielding film 205 and the heat sink 204. The opening 201 may continuously penetrate the shielding film 205, the heat sink 204 and the buffer film 203. Of course, the opening 201 may penetrate all the shielding film 205, the heat sink 204, the buffer film 203 and the support film 202. In the embodiment of the present invention, the opening 201 can be selected penetrate with the number of layers of the thin film structure 20, according to actual needs, no limitation will be given here in the present disclosure.

More specifically, according to the above structure, wherein a thickness of the fingerprint recognition module 30 is equal to a thickness of the thin film structure 20. For example, when the thin film structure 20 includes the support film 202, the buffer film 203, the heat sink 204 and the shielding film 205 respectively stacked on the back surface 102 of the display panel 10. At this time, if the thickness of the thin film structure 20 is less than the thickness of the fingerprint recognition module 30, other layers are added to the thin film structure 20 so that the thickness of the fingerprint recognition module 30 is equal to the thickness of the thin film structure 20. Based on this, the opening 201 in the thin film structure 20 can insert the fingerprint recognition module 30 entirely therein.

It should be also understood that, according to the above structure, the display surface 101 of the display panel 10 has a display area 111 and a non-display area 112. In which, the display area 111 is provided with a fingerprint recognition area 113. The fingerprint recognition area 113 may be disposed on any one position in the display area 111. Therefore, in the display device provided by the embodiment of the present disclosure, since the device is provided with the opening 201 in the thin film structure 20 on the back surface 102 of the display panel 10, and the fingerprint recognition module 30 is disposed within the opening 201. Based on the foregoing structure, it is only necessary to make the opening 201 correspond to the fingerprint recognition area 113 and be located below the fingerprint recognition area 113.

As described above, in the display device according to one embodiment of the present invention, since the device is provided with the opening 201 in the thin film structure 20 on the back surface 102 of the display panel 10. More specifically, the opening 201 disposed on the film structure 20 is configured to correspond to the fingerprint recognition area 113 and located below the fingerprint recognition area 113, and the fingerprint recognition module 30 is disposed within the opening 201. Based on the foregoing structure that not only improves the sensing precision of the fingerprint recognition module 30 but also enables configuration of the fingerprint recognition module 30, not to be limited to the non-display area 112 of the edge of the display panel 10, so as to improve a screen ratio of the display device.

As described above, for example, the display panel 10 is defined to provide display of images and touch operation by input of an instruction, that is, the display panel 10 has a display function and a touch function. The display surface 101 of the display panel 10 has the display area 111 for displaying images and the non-display area 112. Since the display area 111 can also be used for inputting fingerprint information, a space proportion of the display area 111 on the display surface 101 can be greatly increased. On the contrary, a space proportion of the non-display area 112 on the display surface 101 is relatively low.

More specifically, according to the above structure, the fingerprint recognition module 30 is an optical fingerprint recognition device. The optical fingerprint recognition device can emit a sensing light to the outside via the display panel 10, and can receive a sensing light correspondingly reflected back by inputting information from the finger touching with the display panel 10. The sensing light by reflected back is the fingerprint information. In which, the fingerprint recognition module 30 corresponds to a positive projection area located on the display area 111, which is an area where the fingerprint information can be input by a user. Here, the area is defined as the fingerprint recognition area 113. The user may provide the fingerprint recognition module 30 to identify by pressing fingerprints on the fingerprinting recognition area 113. Of course, in the other embodiments which are not illustrated, the fingerprint recognition module 30 may also be an ultrasonic fingerprint recognition device that collects and identifies fingerprints by emitting and receiving ultrasonic waves.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive. The above disclosed subject matter is to be considered illustrative, and not restrictive, and the appended claims are intended to cover all such modifications, enhancements, and other embodiments, which fall within the true spirit and scope of the present invention.

What is claimed is:

1. A display device, comprising:
a display panel having a display surface and a back surface disposed opposite to each other, wherein the display surface has a display area for displaying images;
a thin film structure disposed on the back surface of the display panel, wherein the thin film structure is provided with an opening; and
a fingerprint recognition module configured to identify fingerprint information input from the display area, wherein the fingerprint recognition module is disposed in the opening of the thin film structure;
wherein the thin film structure comprises a support film, a buffer film, a heat sink and a shielding film stacked on the back surface of the display panel; and
wherein the fingerprint recognition module is an optical fingerprint recognition device or an ultrasonic fingerprint recognition device.

2. The display device according to claim 1, wherein the opening penetrates through at least one of the support film, the buffer film, the heat sink, and the shielding film from an outside to an inside of the thin film structure.

3. The display device according to claim 1, wherein the display panel is an active matrix organic light-emitting diode panel.

4. The display device according to claim 1, wherein size of the opening is same as size of the fingerprint recognition module.

5. The display device according to claim 1, wherein a thickness of the fingerprint recognition module is equal to a thickness of the thin film structure.

6. The display device according to claim 1, wherein the display area is provided with a fingerprint recognition area, and wherein the opening corresponds to and is located under the fingerprint recognition area.

7. A display device, comprising:
a display panel having a display surface and a back surface disposed opposite to each other, wherein the display surface has a display area for displaying images;
a thin film structure disposed on the back surface of the display panel, wherein the thin film structure is provided with an opening; and
a fingerprint recognition module configured to identify fingerprint information input from the display area, wherein the fingerprint recognition module is disposed in the opening of the thin film structure.

8. The display device according to claim 7, wherein the thin film structure comprises a support film, a buffer film, a heat sink and a shielding film stacked on the back surface of the display panel.

9. The display device according to claim 8, wherein the opening penetrates through at least one of the support film, the buffer film, the heat sink, and the shielding film from an outside to an inside of the thin film structure.

10. The display device according to claim 7, wherein the display panel is an active matrix organic light-emitting diode panel.

11. The display device according to claim 7, wherein the fingerprint recognition module is an optical fingerprint recognition device or an ultrasonic fingerprint recognition device.

12. The display device according to claim 7, wherein size of the opening is same as size of the fingerprint recognition module.

13. The display device according to claim 7, wherein a thickness of the fingerprint recognition module is equal to a thickness of the thin film structure.

14. The display device according to claim 7, wherein the display area is provided with a fingerprint recognition area, and wherein the opening corresponds to and is located under the fingerprint recognition area.
